(19) United States
(12) Patent Application Publication
(10) Pub. No.: US 2024/0338495 A1
(43) Pub. Date: Oct. 10, 2024

(54) VISUALISATION SYSTEM FOR MONITORING BUILDINGS

(71) Applicant: VEEV GROUP, INC., San Mateo, CA (US)

(72) Inventors: Alon KLEIN, Herzliya (IL); Ori CHAJUSS, Tel Aviv (IL); Noam RONEN, Be'er Tuvia (IL); Israel Jay KLEIN, Kfar Saba (IL)

(21) Appl. No.: 18/292,518

(22) PCT Filed: Jul. 26, 2022
(86) PCT No.: PCT/IL2022/050804

§ 371 Date: Jan. 26, 2024

Related U.S. Application Data
(60) Provisional application No. 63/203,494, filed on Jul. 26, 2021.

(51) Int. Cl. G06F 30/13; G06Q 50/08; G06T 17/05

(52) U.S. Cl. CPC G06F 30/13; G06Q 50/08; G06T 17/05

(57) ABSTRACT

A building monitoring method comprising using a hardware processor for determining coordinates of a physical location within a building and, accordingly, accessing, from computer memory, at least one design file of the building which pertains to a vicinity of location L and which represents data describing an internal structure of at least one object aka building element within the vicinity of location L.

### REFERENCE TO CO-PENDING APPLICATIONS

Priority is claimed from U.S. provisional application No. 63/203,494, entitled “Point cloud prediction for construction applications” and filed on Jul. 26, 2021, the disclosure of which application/s is hereby incorporated by reference in its entirety.

### FIELD OF THIS DISCLOSURE

The present invention relates generally to the building industry and more particularly to visualization of products of the building industry.

### BACKGROUND FOR THIS DISCLOSURE

Wikipedia describes that “Wi-Fi positioning . . . is geolocation . . . that uses the characteristics of nearby Wi-Fi hotspots and other wireless access points to discover where a device is located . . . where satellite navigation such as GPS is inadequate due to various causes including multipath and signal blockage indoors, or where acquiring a satellite fix would take too long. Such systems include assisted GPS, urban positioning services through hotspot databases, and indoor positioning systems. Wi-Fi positioning takes advantage of the rapid growth . . . of wireless access points in urban areas. The most common . . . localization technique used for positioning with wireless access points is based on measuring the intensity of the received signal (received signal strength indication or RSSI) and . . . “fingerprinting”. Typical parameters useful to geolocate the wireless access point include its SSID and MAC address.”

LiDAR is a laser-based “light detection and ranging” method for determining ranges which may be used to generate digital 3D representations of contours, e.g., by varying the wavelength of the light beam. A LiDAR can perform 3D laser scanning, which combines 3D scanning and laser scanning techniques.

ARKit (an application programming interface (API) or SDK), RealityKit (which uses data provided by ARKit) and SceneKit are examples of frameworks to implement AR which facilitate augmented reality aka AR development, by facilitating a developer's ability to place virtual objects on horizontal or vertical surfaces such as walls, doors, floors or windows, providing an ability to detect certain images, say of movie posters or barcodes, artwork, into augmented reality experiences. This facilitates building of augmented reality apps which utilize outputs from a mobile device's camera and/or CPU and/or GPU and/or motion sensors to build virtual objects which may then be integrated into a real-world scene captured by a physical camera. A series of images captured using a phone camera may be converted into 3D models optimized for AR in minutes, using the Object Capture API on macOS, for example.

These toolsets include feature sets for world-mapping, room mapping, semantic segmentation, shared AR, and so forth. For example, by combining information from a LiDAR Scanner and edge detection in RealityKit, virtual objects located under or behind other objects interact with physical surroundings appropriately; only the parts of the virtual object that would be visible to the naked eye are presented, whereas portions of the virtual object, which would be hidden by a physical object, are not presented.

A “Depth API” may be used to give developers access to per-pixel depth information output from a LiDAR e.g., that found on various iPad Pro smartphones.

The disclosures of all publications and patent documents mentioned in the specification, and of the publications and patent documents cited therein directly or indirectly, are hereby incorporated by reference other than subject matter disclaimers or disavowals. If the incorporated material is inconsistent with the express disclosure herein, the interpretation is that the express disclosure herein describes certain embodiments, whereas the incorporated material describes other embodiments. Definition/s within the incorporated material may be regarded as one possible definition for the term/s in question.

### SUMMARY OF CERTAIN EMBODIMENTS

Certain embodiments of the present invention seek to provide circuitry typically comprising at least one processor in communication with at least one memory, with instructions stored in such memory executed by the processor to provide functionalities which are described herein in detail. Any functionality described herein may be firmware-implemented or processor-implemented, as appropriate.

Certain embodiments seek to provide point cloud prediction for construction applications.

Certain embodiments seek to provide a system and method for presenting or displaying augmented reality information, generated by combining physical, camera based, point cloud stream information, with virtual, predicted, point cloud knowledge.

Certain embodiments seek to provide additional information of concealed or interior portions of surroundings, which are concealed from the naked eye or visible light camera or physical camera.

Certain embodiments seek to provide or present or display or project additional information about the constructional and system related aspects of wall internals in a building; conventionally, while interpolation and extrapolation techniques may be deployed for artificially increasing picture resolution or estimating visibility aspects of shadowed areas, internals are typically not displayed.

Certain embodiments seek to provide handling of AR blind spots e.g., by predicting the visibility aspects of areas or regions that are concealed from the current photographic capabilities of the AR arrangement.

Certain embodiments seek to provide a system for virtual object selection and placement e.g., if a user seeks to select a virtual object (e.g., chair near the dining area) and to determine its ideal location within given surroundings.

Certain embodiments seek to provide a system which displays virtual object internals as part of an environment as opposed to conventional AR which typically handles the outer layer of the object without the capability to see within as an integrated wholistic process analyzing the surrounding area.

It is appreciated that any reference herein to, or recitation of, an operation being performed is, e.g. if the operation is performed at least partly in software, intended to include both an embodiment where the operation is performed in its entirety by a server A, and also to include any type of “outsourcing” or “cloud” embodiments in which the operation, or portions thereof, is or are performed by a remote processor P (or several such), which may be deployed off-shore or “on a cloud”, and an output of the operation is then communicated to, e.g. over a suitable computer network, and used by, server A. Analogously, the remote processor P may not, itself, perform all of the operation and instead, the remote processor P itself may receive output/s of portion/s of the operation from yet another processor/s P′, may be deployed off-shore relative to P, or “on a cloud”, and so forth.

There is thus provided, in accordance with at least one embodiment of the present invention,

The present invention typically includes at least the following embodiments: Embodiment 1. A building monitoring method comprising: using a hardware processor for determining coordinates of L and, accordingly, accessing, from computer memory, at least one design file of the building which typically pertains to a vicinity of location L and which represents data describing an internal structure of at least one object aka building element within the vicinity of location L.

Embodiment 2. A method according to any of the preceding embodiments and also comprising superimposing a 3D representation of the internal structure of the at least one building element onto a captured representation of only external features of the vicinity, thereby to yield a superposition of the internal structure and the representation of only external features.

Embodiment 3. A method according to any of the preceding embodiments and wherein the design files were previously used to construct the building.

Embodiment 4. A method according to any of the preceding embodiments wherein the superimposing includes aligning the internal structure to the captured representation.

Embodiment 5. A method according to any of the preceding embodiments and wherein a first subset of the design files of the building which pertains to location L is accessed, and a second subset of the design files of the building which does not pertain to location L is not accessed.

Embodiment 6. A method according to any of the preceding embodiments wherein the aligning includes analyzing the captured representation for unique external features of the building and finding the unique external features in the design files.

Embodiment 7. A method according to any of the preceding embodiments wherein the method searches for the unique external features only in a first subset of the design files of the building which pertains to location L and not in a second subset of the design files of the building which does not pertain to location L, thereby to optimize searching for the unique external features.

Embodiment 8. A method according to any of the preceding embodiments wherein the aligning includes identifying unique tags in the captured representation whose locations within the internal structure are known.

Embodiment 9. A method according to any of the preceding embodiments wherein the building element comprises a wall having plural interior layers and wherein the internal structure comprises data regarding each of the plural interior layers.

Embodiment 10. A method according to any of the preceding embodiments and also comprising selecting an access point to a portion of the internal structure of at least one building element which is represented in the 3D representation, by viewing the superposition, and accessing the portion via the access point.

The portion of the internal structure may for example be a portion of a pipe, which has sprung a leak.

Embodiment 11. A system comprising at least one hardware processor configured to carry out the operations of any of the methods of embodiments 1-13.

Embodiment 12. A computer program product, comprising a non-transitory tangible computer readable medium having computer readable program code embodied therein, the computer readable program code adapted to be executed to implement a building monitoring method comprising: from a physical location L within a building, using a hardware processor for determining coordinates of L and, accordingly, accessing, from computer memory, at least one design file of the building which pertains to a vicinity of location L and/or which represents data describing an internal structure of at least one object aka building element typically within the vicinity of location L.

Embodiment 13. A method according to any of the preceding embodiments and wherein at least one individual design file from among the design files is treated as though the individual design file were a camera feed including providing a stream of images, synchronized to and oriented to a live feed provided by a physical camera imaging the building, and wherein images in the stream of images are constructed from the at least one design file.

Embodiment 14. A method according to any of the preceding embodiments and wherein the physical camera is deployed at a location L and wherein the stream of images is constructed from a perspective of a location which equals the location L.

Embodiment 15. A method according to any of the preceding embodiments wherein the design files also represent external features of the at least one object.

Embodiment 16. A method according to any of the preceding embodiments wherein a first point cloud is reconstructed from a physical camera which captures the captured representation by scanning at least one room in the building, and a second point cloud is reconstructed from the external features, and wherein the first and second point cloud representations are combined and, accordingly, a representation of the external features and the internal structure is presented to an end-user.

Embodiment 17. A method according to any of the preceding embodiments and wherein the second point cloud is reconstructed by a hardware processor from a 3D model of at least one object represented by the at least one design file.

Embodiment 18. A method according to any of the preceding embodiments wherein the design file to access is at least partly determined by detecting a unique identifier of a portion of the building which is of interest and identifying a design file of the building associated in the computer memory with the unique identifier.

Embodiment 19. A method according to any of the preceding embodiments wherein the unique identifier comprises an RFID tag emedded in the portion of the building.

Embodiment 20. A method according to any of the preceding embodiments wherein the unique identifier comprises a QR code borne by the portion of the building.

Embodiment 21. A method according to any of the preceding embodiments wherein the unique identifier comprises a barcode borne by the portion of the building.

Embodiment 22. A method according to any of the preceding embodiments wherein the portion of the building comprises one of: a wall, a ceiling, a floor, a window, a door.

Embodiment 23. A method according to any of the preceding embodiments wherein the unique identifier is supplied by control panels which communicate with a scanning application and transmit the unique identification upon request.

Embodiment 24. A method according to any of the preceding embodiments wherein the unique identifier comprises room verification supplied by a smart home panel.

Embodiment 25. A method according to any of the preceding embodiments wherein the design file to access is at least partly determined by comparing detected external features of a portion of the building with stored external features of plural portion of the building stored in respective plural design files and selecting a design file from among the plural design files which is most similar to the detected external features.

Embodiment 26. A method according to any of the preceding embodiments and wherein an orientation in space of the captured representation is determined and wherein the 3d representation of the internal structure is transformed to match the orientation.

Also provided, excluding signals, is a computer program comprising computer program code means for performing any of the methods shown and described herein when the program is run on at least one computer; and a computer program product, comprising a typically non-transitory computer-usable or -readable medium e.g. non-transitory computer-usable or -readable storage medium, typically tangible, having a computer readable program code embodied therein, the computer readable program code adapted to be executed to implement any or all of the methods shown and described herein. The operations in accordance with the teachings herein may be performed by at least one computer specially constructed for the desired purposes or general purpose computer specially configured for the desired purpose by at least one computer program stored in a typically non-transitory computer readable storage medium. The term “non-transitory” is used herein to exclude transitory, propagating signals or waves, but to otherwise include any volatile or non-volatile computer memory technology suitable to the application.

Any suitable processor/s, display and input means may be used to process, display e.g., on a computer screen or other computer output device, store, and accept information such as information used by or generated by any of the methods and apparatus shown and described herein; the above processor/s, display and input means including computer programs, in accordance with all or any subset of the embodiments of the present invention. Any or all functionalities of the invention shown and described herein, such as but not limited to operations within flowcharts, may be performed by any one or more of: at least one conventional personal computer processor, workstation or other programmable device or computer or electronic computing device or processor, either general-purpose or specifically constructed, used for processing; a computer display screen and/or printer and/or speaker for displaying; machine-readable memory such as flash drives, optical disks, CDROMs, DVDs, BluRays, magnetic-optical discs or other discs; RAMs, ROMs, EPROMs, EEPROMs, magnetic or optical or other cards, for storing, and keyboard or mouse for accepting. Modules illustrated and described herein may include any one or combination or plurality of: a server, a data processor, a memory/computer storage, a communication interface (wireless (e.g., BLE) or wired (e.g., USB)), a computer program stored in memory/computer storage.

The term “process” as used above is intended to include any type of computation or manipulation or transformation of data represented as physical, e.g. electronic, phenomena which may occur or reside e.g. within registers and/or memories of at least one computer or processor. Use of nouns in singular form is not intended to be limiting; thus the term processor is intended to include a plurality of processing units which may be distributed or remote, the term server is intended to include plural typically interconnected modules running on plural respective servers, and so forth.

The above devices may communicate via any conventional wired or wireless digital communication means, e.g., via a wired or cellular telephone network or a computer network such as the Internet.

The apparatus of the present invention may include, according to certain embodiments of the invention, machine readable memory containing or otherwise storing a program of instructions which, when executed by the machine, implements all or any subset of the apparatus, methods, features and functionalities of the invention shown and described herein. Alternatively or in addition, the apparatus of the present invention may include, according to certain embodiments of the invention, a program as above which may be written in any conventional programming language, and optionally a machine for executing the program such as but not limited to a general purpose computer which may optionally be configured or activated in accordance with the teachings of the present invention. Any of the teachings incorporated herein may, wherever suitable, operate on signals representative of physical objects or substances.

The embodiments referred to above, and other embodiments, are described in detail in the next section.

Any trademark occurring in the text or drawings is the property of its owner and occurs herein merely to explain or illustrate one example of how an embodiment of the invention may be implemented.

Unless stated otherwise, terms such as, “processing”, “computing”, “estimating”, “selecting”, “ranking”, “grading”, “calculating”, “determining”, “generating”, “reassessing”, “classifying”, “generating”, “producing”, “stereo-matching”, “registering”, “detecting”, “associating”, “superimposing”, “obtaining”, “providing”, “accessing”, “setting” or the like, refer to the action and/or processes of at least one computer/s or computing system/s, or processor/s or similar electronic computing device/s or circuitry, that manipulate and/or transform data which may be represented as physical, such as electronic, quantities e.g. within the computing system's registers and/or memories, and/or may be provided on-the-fly, into other data which may be similarly represented as physical quantities within the computing system's memories, registers or other such information storage, transmission or display devices or may be provided to external factors e.g. via a suitable data network. The term “computer” should be broadly construed to cover any kind of electronic device with data processing capabilities, including, by way of non-limiting example, personal computers, servers, embedded cores, computing system, communication devices, processors (e.g. digital signal processor (DSP), microcontrollers, field programmable gate array (FPGA), application specific integrated circuit (ASIC), etc.) and other electronic computing devices. Any reference to a computer, controller or processor is intended to include one or more hardware devices e.g., chips, which may be co-located or remote from one another. Any controller or processor may for example comprise at least one CPU, DSP, FPGA or ASIC, suitably configured in accordance with the logic and functionalities described herein.

Any feature or logic or functionality described herein may be implemented by processor/s or controller/s configured as per the described feature or logic or functionality, even if the processor/s or controller/s are not specifically illustrated for simplicity. The controller or processor may be implemented in hardware, e.g., using one or more Application-Specific Integrated Circuits (ASICs) or Field-Programmable Gate Arrays (FPGAs) or may comprise a microprocessor that runs suitable software, or a combination of hardware and software elements.

The present invention may be described, merely for clarity, in terms of terminology specific to, or references to, particular programming languages, operating systems, browsers, system versions, individual products, protocols and the like. It will be appreciated that this terminology or such reference/s is intended to convey general principles of operation clearly and briefly, by way of example, and is not intended to limit the scope of the invention solely to a particular programming language, operating system, browser, system version, or individual product or protocol. Nonetheless, the disclosure of the standard or other professional literature defining the programming language, operating system, browser, system version, or individual product or protocol in question, is incorporated by reference herein in its entirety.

Elements separately listed herein need not be distinct components and alternatively may be the same structure. A statement that an element or feature may exist is intended to include (a) embodiments in which the element or feature exists; (b) embodiments in which the element or feature does not exist; and (c) embodiments in which the element or feature exist selectably e.g., a user may configure or select whether the element or feature does or does not exist.

Any suitable input device, such as but not limited to a sensor, may be used to generate or otherwise provide information received by the apparatus and methods shown and described herein. Any suitable output device or display may be used to display or output information generated by the apparatus and methods shown and described herein. Any suitable processor/s may be employed to compute or generate or route, or otherwise manipulate or process information as described herein and/or to perform functionalities described herein and/or to implement any engine, interface or other system illustrated or described herein. Any suitable computerized data storage e.g., computer memory may be used to store information received by or generated by the systems shown and described herein. Functionalities shown and described herein may be divided between a server computer and a plurality of client computers. These or any other computerized components shown and described herein may communicate between themselves via a suitable computer network.

The system shown and described herein may include user interface/s e.g. as described herein which may for example include all or any subset of: an interactive voice response interface, automated response tool, speech-to-text transcription system, automated digital or electronic interface having interactive visual components, web portal, visual interface loaded as web page/s or screen/s from server/s via communication network/s to a web browser or other application downloaded onto a user's device, automated speech-to-text conversion tool, including a front-end interface portion thereof and back-end logic interacting therewith. Thus the term user interface, or “UI” as used herein, includes also the underlying logic which controls the data presented to the user e.g. by the system display and receives and processes and/or provides to other modules herein, data entered by a user e.g. using her or his workstation/device.

### BRIEF DESCRIPTION OF THE DRAWINGS

Example embodiments are illustrated in the various drawings. Specifically:

FIG. 1 illustrates radar distance measurement for providing depth estimation for use in 3D point cloud generation.

FIG. 2 illustrates point cloud examples.

FIG. 3 illustrates a software example provided by Apple (Prior Art) including ARKit and RealityKit.

FIGS. 4a and 4b, taken together, form a simplified flowchart illustration of a building monitoring method constructed and operative in accordance with embodiments of the present invention.

FIG. 5 illustrates a prefabricated wall system example including multiple layers.

FIG. 6 illustrates an embodiment of the invention which provides, to an end-user, visibility during a multi-stage process (e.g., for a quality control use-case).

FIG. 7 demonstrates a real physical point cloud generated by a real AR camera arrangement.

FIG. 8 illustrates real physical point cloud information identified for a predicted object.

FIG. 9 illustrates a virtual camera which generates virtual point cloud information related to the predicted object.

FIG. 10 illustrates a virtual point cloud registered and anchored correctly with respect to the real physical point cloud.

FIG. 11 illustrates that the ultimate point cloud is the super-position of the real physical point cloud and the virtual point cloud.

FIG. 12 illustrates an embodiment of the invention which provides, to an end-user, visibility of nearby rooms.

Certain embodiments of the present invention are illustrated in the following drawings; in the block diagrams, arrows between modules may be implemented as APIs and any suitable technology may be used for interconnecting functional components or modules illustrated herein in a suitable sequence or order e.g. via a suitable API/Interface. For example, state of the art tools may be employed, such as but not limited to Apache Thrift and Avro which provide remote call support. Or, a standard communication protocol may be employed, such as but not limited to HTTP or MQTT, and may be combined with a standard data format, such as but not limited to JSON or XML. According to one embodiment, one of the modules may share a secure API with another. Communication between modules may comply with any customized protocol or customized query language or may comply with any conventional query language or protocol.

Methods and systems included in the scope of the present invention may include any subset or all of the functional blocks shown in the specifically illustrated implementations by way of example, in any suitable order e.g., as shown. Flows may include all or any subset of the illustrated operations, suitably ordered e.g., as shown. tables herein may include all or any subset of the fields and/or records and/or cells and/or rows and/or columns described.

Computational, functional or logical components described and illustrated herein can be implemented in various forms, for example, as hardware circuits, such as but not limited to custom VLSI circuits or gate arrays or programmable hardware devices such as but not limited to FPGAs, or as software program code stored on at least one tangible or intangible computer readable medium and executable by at least one processor, or any suitable combination thereof. A specific functional component may be formed by one particular sequence of software code, or by a plurality of such, which collectively act or behave or act as described herein with reference to the functional component in question. For example, the component may be distributed over several code sequences such as but not limited to objects, procedures, functions, routines and programs and may originate from several computer files which typically operate synergistically.

Each functionality or method herein may be implemented in software (e.g. for execution on suitable processing hardware such as a microprocessor or digital signal processor), firmware, hardware (using any conventional hardware technology such as Integrated Circuit technology) or any combination thereof.

Functionality or operations stipulated as being software-implemented may alternatively be wholly or fully implemented by an equivalent hardware or firmware module, and vice-versa. Firmware implementing functionality described herein, if provided, may be held in any suitable memory device and a suitable processing unit (aka processor) may be configured for executing firmware code. Alternatively, certain embodiments described herein may be implemented partly or exclusively in hardware, in which case all or any subset of the variables, parameters, and computations described herein may be in hardware.

Any module or functionality described herein may comprise a suitably configured hardware component or circuitry. Alternatively or in addition, modules or functionality described herein may be performed by a general purpose computer or more generally by a suitable microprocessor, configured in accordance with methods shown and described herein, or any suitable subset, in any suitable order, of the operations included in such methods, or in accordance with methods known in the art.

Any logical functionality described herein may be implemented as a real time application, if and as appropriate, and which may employ any suitable architectural option, such as but not limited to FPGA, ASIC or DSP or any suitable combination thereof.

Any hardware component mentioned herein may in fact include either one or more hardware devices e.g. chips, which may be co-located or remote from one another.

Any method described herein is intended to include within the scope of the embodiments of the present invention also any software or computer program performing all or any subset of the method's operations, including a mobile application, platform or operating system e.g., as stored in a medium, as well as combining the computer program with a hardware device to perform all or any subset of the operations of the method.

Data can be stored on one or more tangible or intangible computer readable media stored at one or more different locations, different network nodes or different storage devices at a single node or location.

It is appreciated that any computer data storage technology, including any type of storage or memory and any type of computer components and recording media that retain digital data used for computing for an interval of time, and any type of information retention technology, may be used to store the various data provided and employed herein. Suitable computer data storage or information retention apparatus may include apparatus which is primary, secondary, tertiary or off-line; which is of any type or level or amount or category of volatility, differentiation, mutability, accessibility, addressability, capacity, performance and energy use; and which is based on any suitable technologies such as semiconductor, magnetic, optical, paper and others.

### DETAILED DESCRIPTION OF CERTAIN EMBODIMENTS

Augmented Reality (AR) technology has become increasingly important with the introduction of radar-like technologies (as LiDAR) integrated with high end smartphones and tablets (hence, AR enabled devices as the iPhone 12 Pro Max, iPad Pro 2020, etc.). The use of AR is typically focused on processing an existing environment (including its surroundings and existing objects) and providing the capability to add virtual objects, by facilitating add-on placement capabilities (also known as anchoring) on top of the existing environment, for example, adding a piece of furniture to a living room, or positioning an electrical appliance in a kitchen. As the photographic capabilities of the AR enabled devices are limited to the visible environment, the system suffers from a limitation of being unable to see within, into, or beyond objects whose external features are visible. For example, in the construction industry, there are various use cases, in which revealing the internal wall structure is desirable. While hardware exists which may provide such real time visibility, e.g., ultrawide band millimeter wave radars or X-Ray cameras and other hardware devices, such devices are cumbersome to use, are costly, and may not provide high resolution information, if at all.

A typical Augmented Reality (AR) technology platform, such as, say, Apple's iPad pro 2020, employs at least one camera, used for capturing the visuals of the surrounding environment. In addition, the platform includes an additional depth sensor (e.g., LiDAR) which is capable of providing high resolution object distance information. In some embodiments, more than one camera is used, each camera typically configured with its own lens focal capabilities and resolution for enhancing picture quality, however regular cameras mainly provide two dimensional and color aspects of the surroundings, while the depth sensing elements either provide the missing third dimension (depth) information, or may greatly increase the accuracy of such information, if already provided by some multi lens camera arrangements.

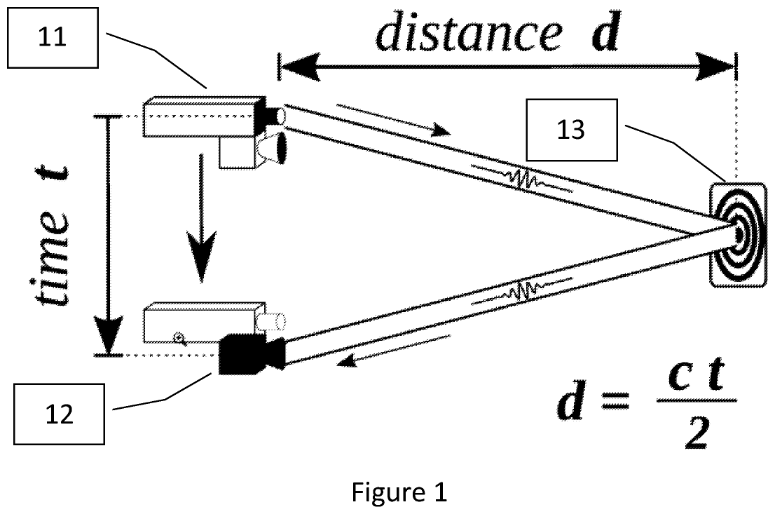

In FIG. 1, conventional depth measurement is illustrated. In a radar system, a transceiver may be provided, typically including a transmitter and co-located receiver. An electromagnetic pulse is transmitted at a certain time (11 in FIG. 1) and sent towards the surrounding area, and when the pulse encounters an object (13 in FIG. 1), the pulse will be reflected back (at least some part of it) and will travel back to the point of origin, being picked up by the receiver part (12 in FIG. 1). The time difference between pulse transmission and reception is twice the distance between the reflecting object divided by the speed of light, hence the object distance (the depth) may be computed. LiDAR uses a similar paradigm with laser light. Typically, the depth information is combined with an image taken by a physical camera.

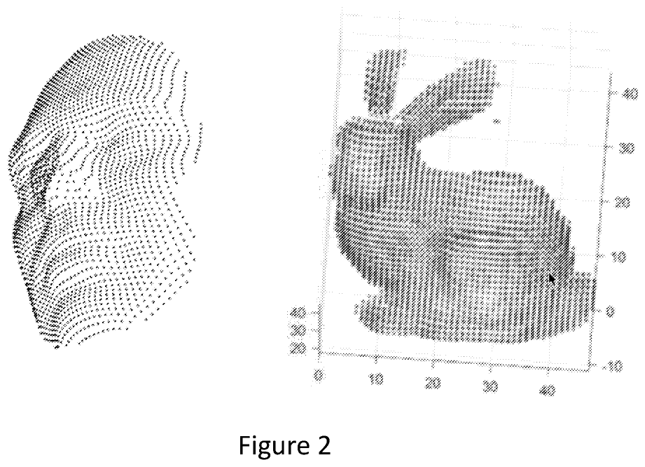

The camera (or cameras, if more than one is installed) and the depth sensor eventually construct a point cloud which is a set of data points in space representing the 3D surroundings. The point cloud data may be a function of time if the surroundings are recorded over time more than once. In FIG. 2, some point cloud examples are presented.

Most AR platforms, e.g., ARKit and RealityKit software by Apple, also include a software toolbox (or toolkit) which provides various tools e.g., functions and procedures which process a point cloud stream eliminating the need of independently developing low-level software code for basic point cloud processing functions. These tools may be used to implement any embodiment herein, both during setup and/or during runtime. A point cloud tool kit may include functions/procedures for displaying images related to the point cloud and/or for processing information of the point cloud itself (e.g., 3D geometrical transformations).

The toolbox may provide basic functions which handle the surroundings—processing the geometrical aspects of the surroundings (image registration) and/or identifying different objects within the surroundings and/or listing or inventorying all objects encounted, as recognized (e.g. recognizing all walls and ceilings and floors that are captured, as well as other recognized objects e.g. electric sockets, doors, windows, etc.), and/or handling additional objects which may be overlaid and anchored by an end user.

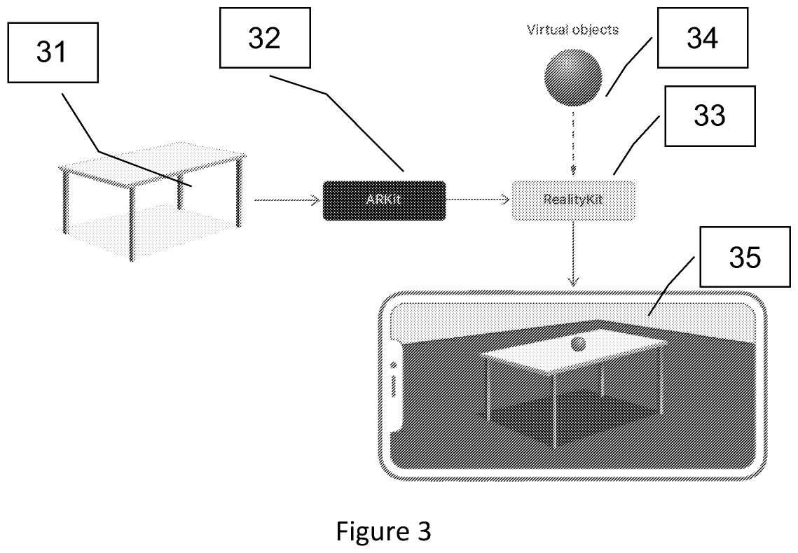

In FIG. 3, a simplified block diagram for the ARKit and RealityKit software by Apple is shown. While the ARKit (32) is mostly focused on processing the surroundings and identifying objects (in the Fig. a table is identified, 31), the RealityKit (33) provides functions for correctly anchoring objects (in the Fig., a ball (34) is positioned on top of a table, 35).

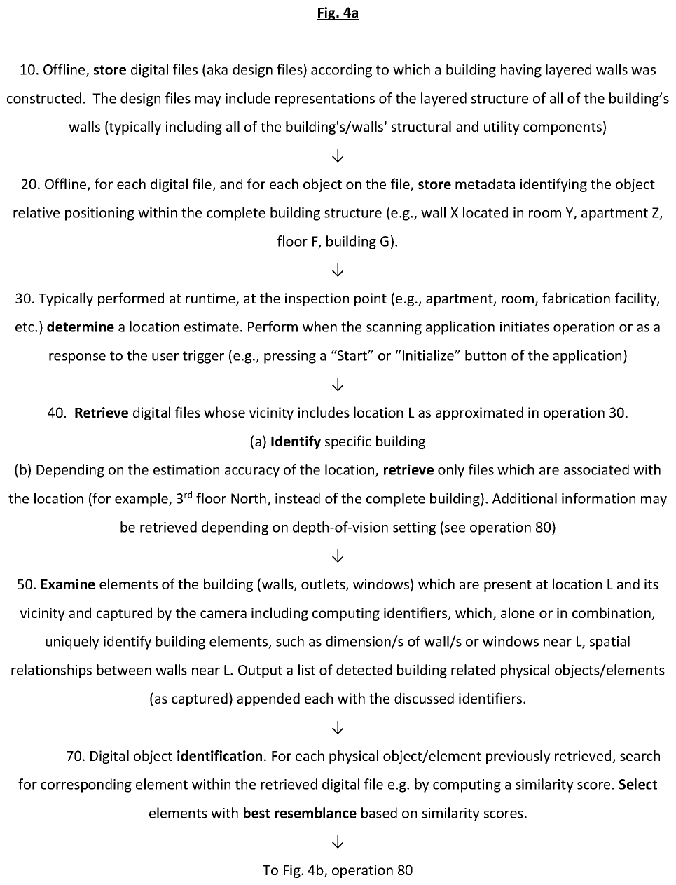

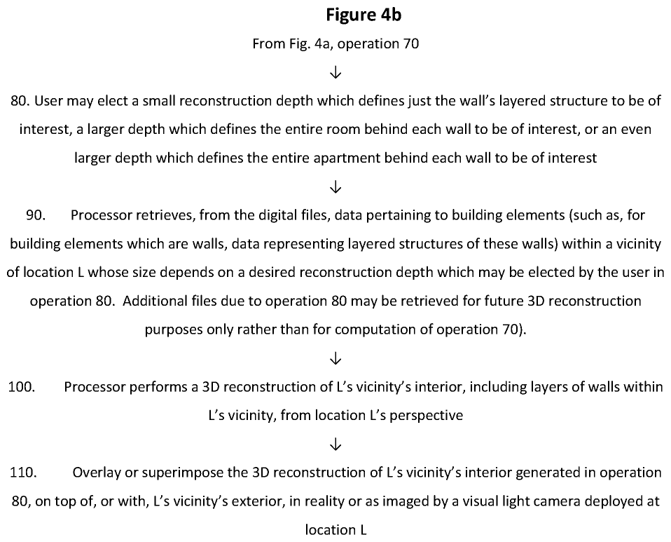

In a basic application example, a smartphone may record the surroundings of an existing building structure, and later use and share this information (e.g., the point cloud stream) e.g., for facilitating a tour of the recorded structure, in order to monitor, renovate, repair, or otherwise interact with the building or structure. In another example, an online furniture shop may support on their smartphone app (application, FIG. 4) the virtual positioning of furniture items within the end user's house using the smartphone's camera (and LiDAR, if equipped therewith). The AR software may be used to establish a point cloud representation of a targeted room or living space. The software may then allow a user to pick and choose a furniture item (e.g., a shop's item) which may be positioned in the 3D space, taking into account the furniture item surface geometry and its dimensions.

The term physical camera as used herein typically includes a LiDAR enabled camera (or equivalent radar-like technology) which includes not only the hardware related components but also the basic software tool kits (e.g. ARKit and RealityKit software by Apple) for supporting any application development which requires LiDAR (or radar-like) technology.

While conventional AR applications and their related background processing are useful for virtual tour arrangements of an existing, pre-defined structure, and may support the addition or overlay of external virtual objects selected by end users of such AR applications, this software typically does not support features such as:
1. Presenting internal depths of existing objects and surroundings; due to limitations of the camera and depth sensing devices, conventional point clouds typically do not include internal structures within the surroundings.
2. Adding an object to the existing surrounding focuses only on the object's surface or external aspects after the object has been selected for positioning, and does not focus on the object's internal aspects.
3. Conditional display of Internal structures of objects by regarding these structures as multi-faceted and then showing various different characteristics conditionally displayed (only if certain conditions apply).

For example, if only certain water and sewage components are relevant to a certain inspection being carried out by a certain end-user, and such components are known to the system and/or to the end-user to be located in a specific layer of the wall (e.g., layer K out of N layers) then the system may display only layer K of all walls; all other layers may be invisible or may be transparent to some (e.g. preset) degree.

Reference is now made to FIGS. 4a-4b, which, taken together, form a simplified flowchart illustration of a building monitoring method constructed and operative in accordance with embodiments of the present invention. The method typically includes imaging the building using a physical (camera deployed at a physical location L within a building to be monitored. The coordinates of L are determined and, accordingly, design files of the building which pertain to a vicinity of location L and which represent data describing both external features of, and an internal structure of at least one building element within the vicinity of location L, are accessed.

For the method of FIGS. 4a-4b, and for processes A-D, it is appreciated that all or any subset of the stipulated operations may be performed, in any suitable order e.g., as stipulated. Also, operations from the method of FIGS. 4a-4b may be mix-and-matched with operations from any of processes A-D.

Operation 10. Offline, typically at the final design and implementation stages of the building, store digital files (aka design files) according to which a building having layered walls was constructed. The design files include representations of the typically layered structure of all of the building's walls, including floors and ceilings, wherein the layered structure typically includes geometrical/architectural/mechanical aspects. The file(s) may have been generated using any suitable software design program, such as REVIT by Autodesk.

Operation 20. Offline, for each digital file, and for each object on the file, store metadata identifying the object relative positioning within the complete building structure (e.g., wall X located in room Y, apartment Z, floor F, building G).

Any suitable format may be used for storing design files and metadata associated therewith.

It is appreciated that each (“master”) design file may include all or any subset of the following: the object type (floor, wall) that is represented in that file, the orientation (e.g. horizontal, vertical, etc.) of that object, relationship aspects (e.g. location where that object is deployed, e.g. relative to some known reference point), hierarchal aspects (objects included such as layers and internal objects e.g. cables and pipes, each of which may be stored in an independent file whose unique identifier and/or location in system memory is referenced by the “master” design file, etc.).

Operation 30—Typically performed at runtime, at the inspection point (e.g., apartment, room, fabrication facility, etc.) for determining a location estimate. This operation may be performed when a scanning application operationalizing any embodiment of this invention) initiates its operation or as a response to the user input (e.g., pressing a “Start” or “Initialize” button of the application). This stage is useful for figuring out which relevant digital files are to be used for further processing. This operation corresponds to the stage when the end-user is seeking to monitor a building, deploys equipment at a location L within a building, such as within a room or corridor, or adjacent the building, equipped with a typically mobile electronic device having a processor which may use an augmented reality (AR) platform, and/or memory and/or screen display and/or visible light camera and/or physical camera and/or networking functionality and/or radio receiver to measure RSSI for WiFi SSID purposes and/or GPS receiver and/or LiDAR sensor (laser, scanner, GPS receiver).

Any suitable technology may be employed for estimating the location, e.g. by direct object identification onsite and/or by assessing geographical related data. Selection of suitable technology depends on availability. For example, some buildings may be known to have barcodes (say) on objects such as walls, uniquely identifying each such object, and design files for these objects are associated with the unique identifiers represented by the barcodes or other uniquely identifying indicia. buildings may be known to have RFID tags embedded in objects such as walls, uniquely identifying each such object, and design files for these objects are associated with the unique identifiers represented by the RFID tags.

In direct object identification, location may for example be determined as follows:
1) Available barcode on any building object present (at the scanned location as a room wall) or
2) Available RFID tags which are embedded within the building object and can be electromagnetically scanned for retrieving object identification data
3) Room or home control panels which either communicate with the scanning application and transmit identification details upon request or display a barcode (similar to the first option)
4) Address details, either entered manually (street, building number, apartment number) or by automatic retrieval from other applications (e.g., navigation apps) where design files for a given apart are associated in memory with the apartment's number and the apartment's building's number.

In the second case, location can be determined, yet not limited to the following examples:
1) GPS coordinates
2) WiFi station ID (SSID) which typically relates to a specific building region
3) Device IP address which may indicate by sub net structure the precise building region or floor

When location is estimated by assessing geographical related data then typically, when a software program, implementing any method or operation herein runs on a tablet or smartphone device, or any dedicated equipment which integrates similar computational display and interactions, the software has access to built-in components of the device. For example, the pre-existing WiFi module of the device which provides Internet connectivity, may be queried regarding its radio connectivity status, including the current access point the WiFi module is connected to (SSID—Service Set IDentifier), and/or received radio signal levels may be queried and may then be used for rough estimation of distance from the access point location, and/or the IP address may be queried since this address may be indicative of specific subnets being used which, in turn, are associated (e.g. in a suitable memory table, pre-loaded) with building locations (floor level, building regions such as “roof”, “basement”, “parking” etc.), and/or GPS module parameters may be accessed if available (e.g. using last known location coordinates etc.).

Operation 40. Retrieve digital files whose vicinity includes location L as approximated in operation 30. Retrieval may occur hierarchically. First, a specific building from among many buildings (in a given project comprising multiple buildings built and maintained together, say) is identified by location. This enables all design files for that building to be identified. Depending on the estimation accuracy of the location, the file retrieval process may be further focused and retrieve only certain files which are associated with the location (for example, 3^{rd} floor North, instead of the complete building). If the location estimation provides higher accuracy information, then the software may further pinpoint and focus retrieval to access only design files associated with that location (for example, 3^{rd} floor, apartment 3025, bedroom 1) etc.

The amount of additional information (“more files”) depends typically on a depth-of-vision setting. For example, if the user selects to only visualize nearby walls, then only components/objects near location L are retrieved and revealed. If the user selects a deeper level (e.g., “floor transparency”) the entire floor (e.g., all apartments on the fifth floor) may be retrieved and revealed or presented to the end-user.

Operation 50. Examine elements of the building (walls, outlets, windows) which are present at location L and its vicinity and captured by the physical camera including computing identifiers, which, alone or in combination, uniquely identify building elements, such as dimension/s of wall/s or windows near L, spatial relationships between walls near L.

These identifiers may be computed by capturing images of location L's vicinity using a physical camera deployed at location L, then processing the images to identify building elements in the images, and to characterize those building elements; e.g. as described with reference to FIG. 3 where a typical AR software toolkit may be used for performing actions.

The end-user may utilize his device's physical camera to image a panoramic view of the vicinity of location L e.g., by capturing a video sequence or plural stills. During this 1^{st} scan, geometrical aspects of the room (or other building area which is being scanned) may be retrieved.

The end result of operation 50 typically comprises a list of detected building related physical objects/elements (as captured) typically each appended to or otherwise associated with the discussed identifiers e.g. as metadata associated with respective captured objects/elements.

Operation 70—Digital object identification. For each physical object/element retrieved in operation 60, a search is performed for the corresponding element within the retrieved digital files at operation 50. At this stage, e.g. as described below, for each element on the output list of operation 60, when compared with a candidate object retrieved from the corresponding digital files (and matching the type of object of the physical object), a similarity score may be computed. The similarity score may be computed by comparing identifiers of the physical component with identifiers of the candidate component. The score typically reflects the accumulated differences between these identifiers. For example, if the identifiers are based on dimensions, then one possible score may sum absolute difference values between the physical and candidate object.

After all candidate objects are scanned and compared with the physical object, the best candidate (measured from a resemblance/similarity score perspective as being most similar) is selected. This process may be repeated for all physical objects on output list of operation 60.

Operation 80. A user may elect a reconstruction depth value e.g., a small value which defines just the wall's layered structure to be of interest, a larger depth which defines the entire room behind each wall to be of interest, or an even larger depth which defines the entire apartment behind each wall to be of interest. According to the selection, additional files may be retrieved for future 3D reconstruction purposes rather than for computations of operation 70).

Operation 90. A processor retrieves, from the digital files, data pertaining to building elements (such as, for building elements which are walls, data representing layered structures of these walls) within a vicinity of location L whose size depends on a desired reconstruction depth which may be elected by the user in operation 80.

Operation 100. A processor performs a 3D reconstruction of L's vicinity's interior, including layers of walls within L's vicinity, from location L's perspective.

Any suitable scheme may be employed to display data regarding interior features, to an end-user. For example, the locations of pipes or electric cables within a wall may be shown visually, e.g. superimposed on an image of the wall captured by the end user's physical camera. Or, color coding (or other visual textures) may be used to represent data. For example, an acoustic isolation layer could be set to be displayed as translucent green whereas a thermal isolation layer is represented in another color.

Operation 110. Overlay or superimpose the 3D reconstruction of L's vicinity's interior generated in operation 80, on top of, or with, L's vicinity's exterior, in reality, or as imaged by a physical camera deployed at location L. Typically, a first point cloud is reconstructed from the actual physical camera which scans the room, and a second point cloud is reconstructed from the “virtual camera” the system provides, which generates augmented reality images using design files matching location L, as described above. Typically, both point cloud representations (that were reconstructed from the actual physical camera and that were retrieved from design files of the designed objects) are combined. Typically, each file retrieved is analyzed including a point cloud being reconstructed for data within that file, such as a 3D model of the object represented by that file.

It is appreciated that non-structural, movable objects in the building e.g., add-on components such as tables, sofas, and other furniture, may be handled as well, etc. The user may, for example, be able to “see” non-structural components e.g., to see all furniture of all apartments of all floors.

It is appreciated that many variants of the operations of FIGS. 4a-4b are possible, of which processes a-d, presented in detail below, are merely examples. Thus, merely by way of example, in Process A, objects to be visualized may be building related elements or objects (e.g., walls) whose visual information is reconstructed based on the digital design files of the building. Process A may assume that the objects processed and visualized are the visible objects in the vicinity of the user (and of the physical camera). Process B is a modification of Process A which handles objects which are fixed add-ons rather than being an intrinsic part of the building, such as closets or kitchen cabinets which include compartments, internal drawers, shelves and other elements or objects which are not visible to the end user when the closet doors are closed. These elements may also be represented as digital design files (e.g. the files according to which the closets or other objects were constructed in the first place) which may be accessed, processed, analyzed and at a later stage used, say, for 3D point cloud superposition for supporting a complete display of the surroundings. Process B, like process A, handles visible objects in the user's vicinity. Process C is advantageous for use-cases which seek to visualize characteristics of nearby rooms or areas e.g. rooms or interior spaces other than the room or space in which the end-user is located. For example, a user may be located in one apartment's bedroom yet may require visibility of rooms and corridors other than the bedroom (e.g. so as to follow wiring or pipe installation). Process D extends process C to serve a use-case where other building apartments and areas need to be visualized from the user location. It is appreciated that the flow structure and/or data access and/or retrieval, and/or 3D reconstruction for display purposes, may be similar across processes. For example, the digital file retrieval may be based on location related information (either absolute e.g. home address or relative e.g. with nearby walls or apartments). Another example is use of a superposition process to overlay and present multiple point clouds.

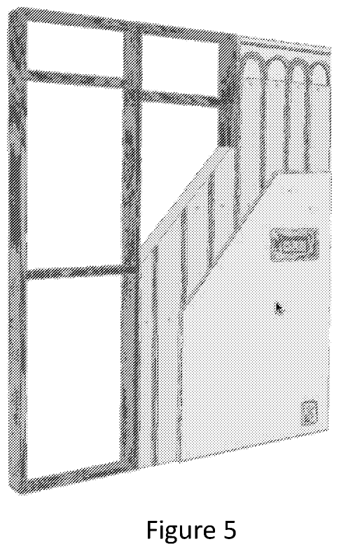

The following case, which relates to the embodiment of FIG. 5, is discussed merely by way of non-limiting example:

Consider the case of a prefabricated constructed building. Walls and floor cassettes of the building may be manufactured (fabricated) in advance, typically off-site (not at the construction area), and later be transported to the site for final installation. Walls and floor cassettes of the building may be manufactured (fabricated) e.g., as described in co-owned patent document entitled Prefabricated Construction Wall Assembly, published as WO 2020/012484 (or https://patents.google.com/patent/US20210148115A1/en).

The wall (FIG. 5) and/or floor cassettes may each comprise multi-layered structures which include not only the visible layers (e.g., the outer wall finish) but also structural components e.g., all or any subset of framing, tension systems, acoustic and fire insulation layers, plumbing infrastructure, electrical distribution systems, climate control (e.g., radiant heating and cooling), and smart home systems. Each wall or floor cassettes may have a complete electronic file (e.g., Revit file) which includes an exact digital representation with all details needed for constructing the cassette.

At some stage, say e.g., when the construction has been finalized, and the complete building is ready for habitation, AR technology may be deployed for visualizing building internals.

Any “fixed” component or element, whether indoor or outdoor, may be relevant for display. A window frame is a “fixed” component whereas chairs are movable. However, if one wishes to “simulate” certain furniture elements to sense and feel the occupancy particulars, then a fixed furniture structure (unrelated to the physical real-time location of furniture which may be physically present) may be presented, e.g. superimposed on an image of the room captured by the end-user's physical camera.

An application and related software may be provided to facilitate such a process, in which case the process (aka “process A”) may include all or any subset of the following operations a1, a2, . . . , suitably ordered e.g., as follows:
a1. Use current cameras and depth sensors (LiDAR) for constructing the real physical point cloud Pr of the surroundings
a2. Use AR toolbox (e.g. RealityKit software by Apple) existing capabilities such as identification and classification of objects and their related geometrical data (e.g., shape, dimensions, etc.) for identifying and classifying objects such as, say, a wall, table, chair, cabinet, window.
a3. For the walls, floor, and ceiling area, retrieve:
   a. Dimensional data (e.g., size)
   b. Geometry type (e.g., rectangle, trapezoid, polygon)
   c. Existence of surface functions (e.g., windows, doors)
   d. External integrated and visible features (e.g., electrical outlets, plumbing related functions, smart home panels)
The data may be generated by AR toolbox (e.g. RealityKit software by Apple) processing of the current surroundings. The data may be stored in the AR toolbox database and may be accessible by specific data search and retrieval functions of the AR toolbox. For example, the AR toolbox may list objects encountered in its database, and may report back, after analysis, the number of objects identified, N. The software may access each element by requesting element K (out of N) and receiving back a data record which has some predefined structure (e.g., type and/or dimensions and/or location.).
a4. Geo-location related data is supplemented, including:
   e. GPS
   f. Wireless Network nearby
   g. Room verification by smart home panel or smart home devices
   h. Visible address including apartment or suite number.
If the end-user is using a smartphone or tablet or any other device which has geolocation modules embedded in and/or and accessible to the device's internal operating system, then geolocation information may be accessible via the device's GPS or wireless network related information (e.g., SSID). The AR toolbox (e.g. RealityKit software by Apple) information may be tagged with this information and a “location” relationship may be established. If other location related data is available (e.g., c and/or d above) they may be used for tagging alternatively or in addition.
a5. a set, S, of possible electronic files of the walls and floor cassettes is retrieved e.g., based on operation (a4). For example, floor location may be employed e.g. if the location is @floor K, files which contain the floor K design are retrieved. The “floor” relationship may for example be embedded in each design file name and/or in each design file's metadata and/or may be implemented by a cross index/reference configuration file.
Examples:
   a. The naming scheme used to name design files of a given project including plural buildings may be BXXXFYYYAZZZ, where B stands for building number, F for floor number, A for apartment number etc.
   b. To use a cross reference file, e.g. if file names have no known convention such that no location information is known to be included in a file's name or metadata, a “master file” may be provided which may contain a table of all file names in one column and may contain associated location information in other column(s). Another table may be built from this table which cross references the location with a list or set of associated with that location. When a specific location is referenced, the tables may be used for cross referencing and pointing out, then retrieving, files relevant to this specific location.
a6. Based on operation (a3), candidate walls and floor cassettes are selected from the set S (e.g. of operation a5) established by a likelihood score. For example, the score may be constructed by a combined analysis of several aspects, such as computing the difference in dimensional data (actual versus candidate), or by verification of existing visible features (e.g., number of electrical outlets, actual versus candidate) etc. Machine learning algorithms may be employed for better resolution. For example, the location may be estimated to be a certain apartment such as perhaps Apt. 213 in Building #3. Design files relevant to this apartment are retrieved and 26 walls are found, each having certain geometrical aspects including external and/or internal dimensions of the wall. The camera and AR toolbox after scanning the room, list a wall object with certain external dimensions, say 2.82 meters by 6.02 meters. The 26 walls may then be compared by dimensions to the AR toolbox object and each wall may be given a score e.g., the sum of the absolute deviations of each wall's dimensions from the object's dimension. For example, if wall number 18 is 2.9 meters by 5.8 meters according to its design file, then wall 18's score may be 0.08+0.22=0.3. All walls' scores are computed and the wall with the lowest score may be selected. Alternatively, a finer assessment may be established e.g., by including other elements or other dimensions e.g., matching the number of outlets (on the wall) discovered by the AR toolbox (e.g. RealityKit software by Apple) and their location, to the number of outlets in the design file.
a7. If more than one (above-threshold) candidate exists for an actual wall or floor cassette, then the candidate options are presented to the application end-user for verification and selection. In all other cases, the candidates may either be automatically verified and registered, or may be verified first by the end-user.

For example, the user may be presented with options. If there are two possible walls whose design files indicate dimensions of close to 2.82 meters by 6.02 meters, such as bedroom1's north wall and also bedroom2's east wall, both of these “candidates” may be displayed to enable the user to intervene by selecting between them.
a8. Design files of all verified and registered candidates may be retrieved, and a relative point cloud, Ci, is constructed. As each Ci is typically multifaceted (e.g., includes various systems and layers), certain visual aspects of Ci may be defined as conditional or elective (e.g., the user may be empowered by the application to elect what is visible, and what is not). The condition (e.g., as defined for an explicit analysis) may determine which parts of the data in each electronic file will be retrieved for constructing Ci. For each Ci, the registration process with the physical real point cloud Pr is done using an AR toolbox (e.g. RealityKit software by Apple) hence anchoring Ci correctly with Pr.
a9. A virtual point cloud, Pv, including all verified and registered candidate point clouds Ci, may be constructed by super-positioning all of the candidate point clouds, Pv=ΣCi. Super positioning is typically performed after registration and anchoring, enabling the treatment of all walls and floor cassettes as a whole entity.
a10. The ultimate point cloud is P may be computed as a super-position of the real physical point cloud Pr (data based on cameras and depth sensors) and the virtual point cloud Pv (data based on automatically retrieved data from walls and floor cassettes files).
Example:

A wall is identified by the system, and additional information, retrieved from the wall's electronic file, is transformed into an additional point cloud augmenting the existing reality.

According to certain embodiments, while one component of the ultimate or final point cloud actually displayed to the end user is the real physical point cloud Pr which is retrieved using physical cameras and depth sensors, other component/s of the ultimate point cloud, aka virtual point cloud Pv, may be retrieved by “virtual cameras” which are not physical cameras which capture real images, and instead include processors configured to reconstruct images from digital files based on location and orientation information provided by the real camera. Eventually, an augmented reality visualization of the room (say) is provided by combining both “cameras” e.g., by superimposing the reconstructed images on the camera-captured real images of the room which recall their related point cloud data from pre-existing electronic files of the walls and floor-cassettes. As the retrieval process is done automatically by processing the real physical point cloud, this operation is seamless and typically comprises superposition. If one camera provides, per point cloud, at least one variable representing by value some display aspect (e.g., color level) and the second camera provides a similar type of variable representing by value a similar display aspect, the combination of both may be a (weighted) sum of both values which represents the unification of images from both cameras. The end user experience is as though there were multiple camera types, including not only a visual-light camera, but also a camera which “sees” the wall's innards.

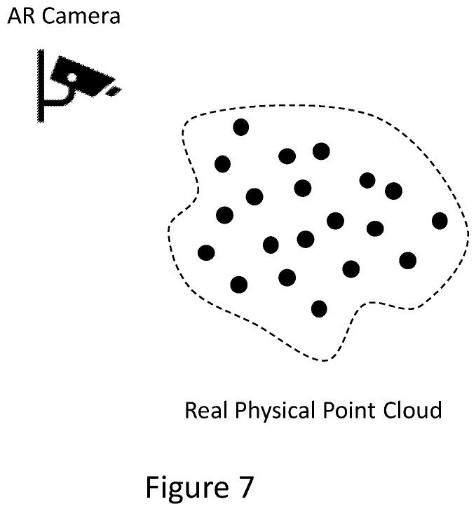

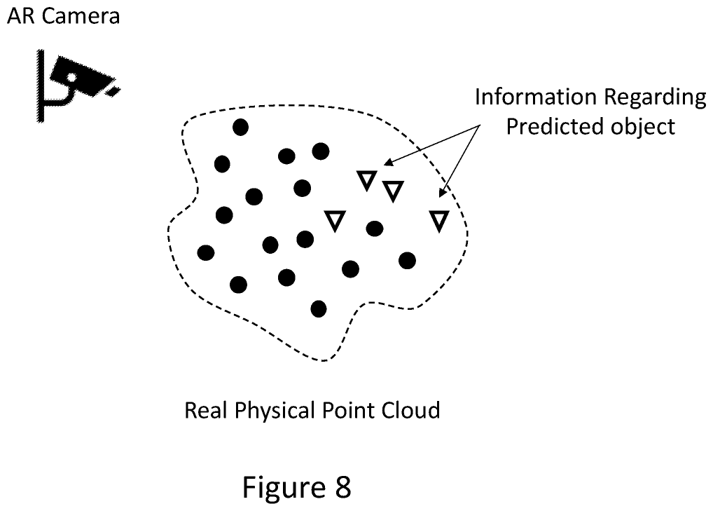

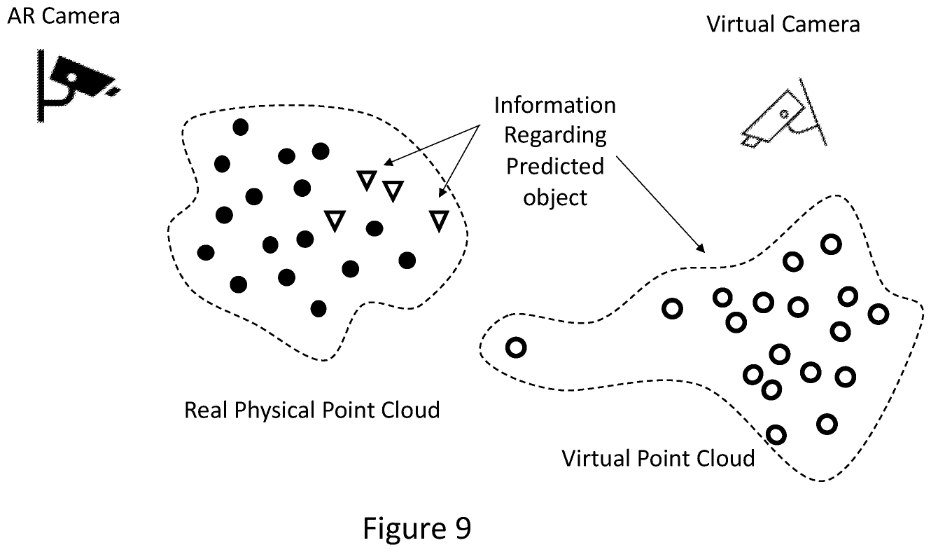

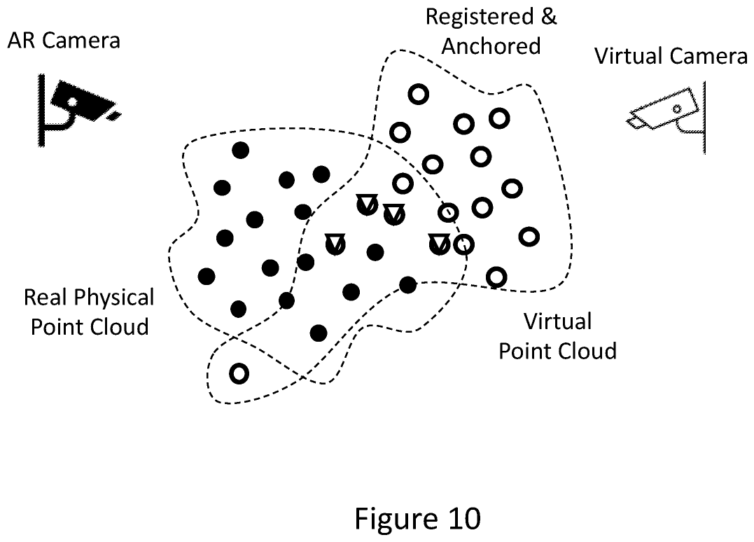

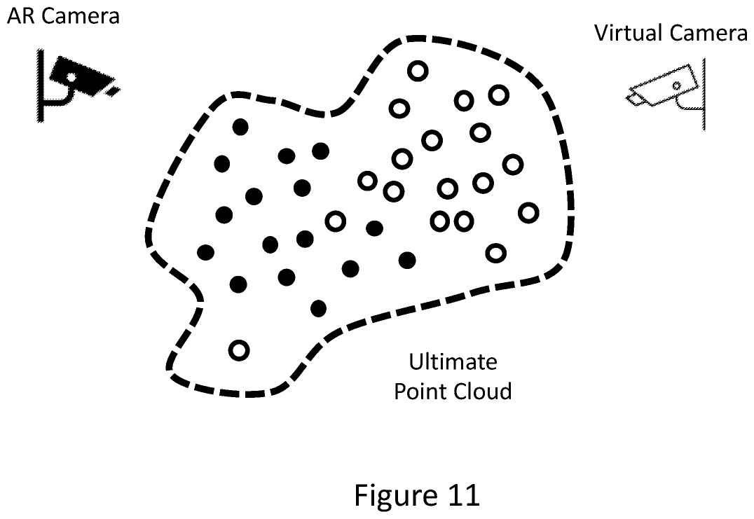

Reference is now made to FIGS. 7-11. In FIG. 7, an AR camera arrangement picks up the real physical cloud point. In FIG. 8 some information in the real physical cloud point is identified and classified as a predicted object, for example, a wall which exists in the environment but is only revealed through its visible parts. The algorithm identifies the correct candidate object and the wall's related cloud point is retrieved from its electronic file. This is represented in FIG. 9 as an additional “virtual camera” which “picks up” the walls' visible information. In FIG. 9, the wall's point cloud is not yet aligned correctly with the real physical cloud point, and, typically, the wall's point cloud is subsequently registered and anchored correctly as demonstrated in FIG. 10. Additional information supplied by the virtual camera may include information not directly related to the wall which is part of or characterizes another area in the surroundings. The end result in FIG. 11, is an ultimate point cloud which is the super-position of the two camera arrangements, one real, and one virtual e.g., by computing a simple or weighted sum of corresponding pixels in the image provided by the physical camera and in the image reconstructed by the “virtual camera”. If an existing tool is employed to superimpose point clouds of two cameras, this tool may be activated on the outputs of the physical camera and “virtual” camera.

The virtual point cloud may include additional pre-constructed or prefabricated objects, beyond the walls and floor cassettes. These may, for example, include cabinet objects, window objects, door objects, exterior cladding objects, and other objects which populate the building.

According to an embodiment, the user may enter a certain house or apartment. The application may start to retrieve, in the background, the set of electronic files related to the walls and floor cassettes. Any suitable technology may be employed to determine which design files to retrieve e.g., by sensing the end-user's motion (e.g., by motion sensors of the smartphone/tablet) or by the image being “fixed” for some predefined time), or retrieval by user input, e.g. if an end-user points at some particular item on a display of a building or room or a dedicated “button” which is used for activation/deactivation. The user then scans the room using the AR based application shown and described herein (e.g., as per any of the operation/s of FIG. 4), and likely candidates are identified which may be used for constructing the complete ultimate point cloud.

Based on the end user's configuration, if supported by the app's user interface, certain aspects of the walls and floors may either be visible, or not. For example, in a maintenance event which concerns the plumbing network, the user (or the user's type e.g., “plumber”) may elect that only some minimal structural information is displayed, plus the detailed plumbing network is revealed. In contrast, in the case of electrical repairs, only electric cable information may be overlaid onto the physical camera's output. Other systems or aspects may be hidden (not presented) to avoid visual clutter, that the user, e.g., due to her or his profession, is known not to need, or that the user elects not to see. The end user may decide, through the process, to hide or reveal certain layers according to some menu choices the app may support, hence conditioning visibility e.g., as described with reference to process A, operation a8. In another example, closet pod internals, or shower room internals, may be also revealed when required, as the scope of the invention may be extended to any pre-constructed objects. The type of object to be handled and presented by the application may typically be selected through the application settings.

It is appreciated that prefabricated construction is but an example of possible use-cases for the embodiments shown and described herein.

More generally, a process (aka “process B”) may be provided which includes all or any subset of the following operations b1, b2, . . . , suitably ordered e.g., as follows: Use current cameras and depth sensors (LiDAR) for constructing the real physical point cloud Pr of the surroundings;
b1. AR toolbox existing capabilities (e.g. RealityKit software by Apple) are used for identifying and classifying existing objects within the surroundings;
b2. For existing objects whose internal information is either missing or incomplete and may require elaboration (which may be termed predicted objects herein), retrieve:
   a. Dimensional data (e.g., size)
   b. Geometry type (e.g., rectangle, trapezoid, polygon)
   c. Existence of unique features (e.g., holes, corners)
   d. External integrated and visible features (e.g., handles, coloring, etc.)
b3. Geo-location related data is supplemented, including:
   e. GPS
   f. Wireless Network nearby
   g. Visible address including apartment or suite number
b4. At this point a possible set, S, of electronic files of the predicted objects (4), may be provided.
b5. Based e.g. on operation (b3), candidate predicted objects are selected from the set S (e.g. of operation b4), established by a likelihood score. For example, the score may be constructed by a combined analysis of several aspects, such as computing the difference in dimensional data (actual versus candidate), or by verification of existing visible features (e.g., number of certain external features, actual versus candidate) etc. Machine learning algorithms may be employed for better resolution.
b6. If more than one candidate exists for a predicted object, then the candidate options are presented to the application end-user for verification and selection. In all other cases, the candidates are either automatically verified and registered, or verified first by the end-user.
b7. For at least one object e.g., for all verified and registered candidates, their electronic file is retrieved and their “relative point cloud”, Ci, is constructed.

A relative point cloud is a point cloud constructed using specific location and orientation parameters which may be user-defined, system-defined, or extracted from another point cloud. For example, a cube with its surfaces may be defined and stored as leveled object with no orientation (sides are parallel to planes XY, YZ, XZ). When a “location” and “orientation” are retrieved from some other source, the cube may be “shifted” or translated to that location and rotated according to that orientation.

Methods for applying transformations to point clouds are known and are described e.g., here: https://libpointmatcher.readthedocs.io/en/latest/Transformations/. As described, “The outcome of a point cloud registration is some rigid transformation which, when applied to the reading point cloud, best aligns it with the reference point cloud. . . . Rigid transformations can be rotations, translations, and combinations of the two”.

It is appreciated that a point cloud reconstructed by a virtual camera for a given location may be transformed into a “relative” point cloud e.g., by transforming the reconstructed point cloud to match the orientation and/or location of a physical camera imaging that location's vicinity.

As each Ci is multifaceted (e.g., may include plural systems and/or layers and/or and features), certain visual aspects of Ci are conditional (e.g., what is visible, and what is not). The condition (as defined for an explicit analysis) may determine which parts of the electronic file will be retrieved for constructing Ci. For each Ci, the registration process of the C_i with the physical real point cloud Pr (representing data captured by the camera) is done using an AR toolbox (e.g. RealityKit software by Apple), hence anchoring Ci correctly with Pr.

It is appreciated that a “point” in a point cloud, when displayed to the end user, may use a 2D representation whereas in fact, this “point” may conceal multiple objects/wall layers/etc. For example, consider 2 different objects or 2 layers of the same wall. A “combination algorithm” may stipulate that if both objects are “turned on” (from a visibility aspect, meaning that it is desired that both objects should be seen) then if point Qi is occupied by both objects then Qi should be displayed as a black point, whereas if both objects are absent (at point Qi) the point Qi should be displayed as transparent. If only one object occupies Qi, then its properties (e.g., color) are displayed. By this definition, turning an object on or off will visibly affect the display at point Qi and achieve an effect of combining both objects (from visual/display perspective).
b8. A virtual point cloud, Pv, including all verified and registered candidate point clouds Ci, is constructed by super-positioning all of them, e.g., using a simple or weighted sum Pv=Y Ci. Typically, super positioning is performed after registration and anchoring, which enables the treatment of all predicted objects as a whole entity.
b9. The final output, aka ultimate point cloud P, is the super-position of the real physical point cloud Pr (data based from cameras and depth sensors) and the virtual point cloud Pv (data based on automatically retrieved data from predicted objects files).

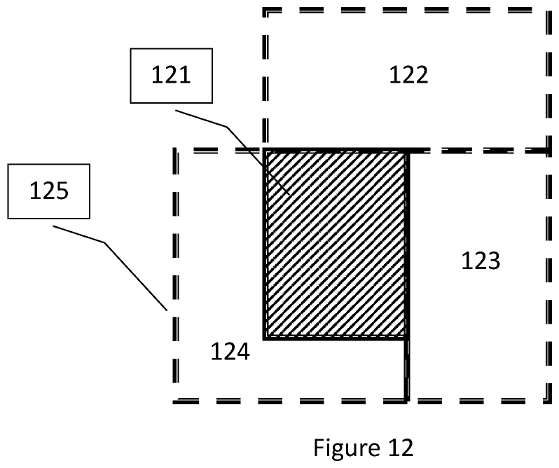

In another embodiment, retrieved predicted objects may include concealed objects located in adjacent surroundings. For example, while in an apartment building, at apartment Ai, in room Rj, on Floor Fk, certain objects (e.g., walls, floor cassettes) related to the surrounding rooms (Rⱼ₋ᵢ,Rⱼ₊₁) or adjacent apartments (Aᵢ₋₁, Aᵢ₊₁) or objects related to the floors above or below when applicable (Fₖ₋₁,Fₖ₊₁) may be included for presenting a comprehensive, widespread, picture of the surroundings. For example, in FIG. 12, the room 121 in which the user's mobile device, which typically has AR equipment, is deployed, is surrounded by adjacent rooms (122,123,124) some of whose walls are common to room 121, and are retrieved whenever room 121 is visualized, while some other walls such as wall 125 in room 124, which is not common to room 121, may be retrieved, as a result of room 124 being adjacent to room 121. This “nearby room” feature can typically be enabled or disabled by the user, via the software application implementing operations herein. Typically, object types to be included in this extended visibility may be selected. For this embodiment, a process may be employed, in which, unlike previous flows, an additional virtual point cloud Pe (aka extended visibility point cloud) is introduced, which is a super-position of point clouds Ej, each related to an object in a set Se of objects (aka “extended objects”, such as walls of adjacent rooms not shared with the room in which location L is located) whose electronic files are to be retrieved. The discovery of the objects in set Se is typically available because the complete structure (e.g., full building) is also available electronically and digitally, and some of the predicted objects are shared (e.g., common walls, floor of one room is the ceiling of the room below).

In a process performed according to this embodiment (aka “process C”), all or any subset of the following operations c1, c2, . . . may be performed, suitably ordered e.g., as follows:
c1. Retrieve full structure data (e.g., building file).
c2. Set extension parameters (e.g., retrieve nearby walls)
c3. For all predicted objects, check if common or shared. If common or shared, then using the full structure data retrieved in operation (1) and extension parameters retrieved in operation (2), retrieve additional predicted extended objects
c4. For all predicted extended objects retrieve electronic file, create point cloud Ej, verify and register relative to the ultimate point cloud P or real physical point cloud Pr
c5. Super-position all point cloud Ej and create an extended virtual point cloud Pe=ΣEj
c6. The adjusted ultimate point cloud P′ is the super-position of ultimate point cloud P and Pe.

Thus, while some part of the adjusted ultimate point cloud P′, the real physical point cloud Pr, is retrieved using physical cameras and depth sensors, the other parts of the ultimate point cloud, the virtual point cloud Pv and the extended virtual point cloud Pe, are retrieved by virtual cameras which recall their related point cloud data from pre-existing electronic files of predicted objects (e.g., the walls and floor-cassettes). As the retrieval process is done automatically by processing the real physical point cloud, this operation is seamless, and the end user experience is as though there are multiple camera types including a physical camera and another “virtual camera” which “sees” internal features of objects whose exteriors are captured by the physical camera, although, in fact, the information provided by the virtual camera is retrieved from memory, rather than captured optically; “penetration depth”, aka reconstruction depth, may typically be controlled e.g. as described herein.

In general, the adjusted ultimate point cloud P′ may be regarded as a super-position of multiple sources:

$${P}^{′} = Pr + \sum {q}_{i} {U}_{i}$$

where Ui is a predicted point cloud retrieved automatically using the information in Pr and the electronic files in a database. It is appreciated that qᵢ represents the visibility of Uᵢ hence qᵢ is typically either 0 (hidden) or 1 (revealed). If each predicted point cloud Uᵢ is constructed from different layers, segment, or parts of which visibility control is required, then Uᵢ may be written as:

Uᵢ=ΣwⱼVⱼ

where Vj is either a layer, segment or part of Ui with visibility control wj (again, 0 representing hidden, 1 representing revealed). For example, V1 may represent the framing structure and V2 may represent the plumbing system of the wall U3.

In processes A, B, C, D . . . herein, operations may be performed during setup or during runtime, as appropriate e.g., depending on the use-case. For example, if during setup, a location/orientation was established, this operation may not be repeated in runtime; instead, the location and/or orientation as established may be monitored and adjusted if and as needed periodically (e.g., every 10 seconds) and only if a large deviation is detected (for example, if the score of objects selection crosses some predefined threshold), would the system re-establish correct object association) in runtime. Thus, these operations may be performed both at setup and runtime, where during runtime the focus is typically on displaying the combined point clouds while periodically checking if deviations are too high (over threshold) in which case a new “set up” process may be initiated.

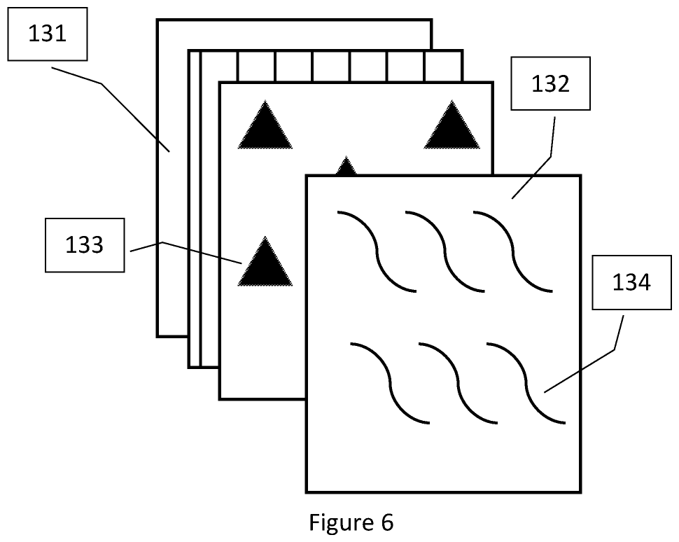

Another embodiment provides process progress discovery (journey discovery). For example, (e.g., see FIG. 6) a prefabricated wall including multiple layers and systems is built in stages. At first the framing structure is constructed, followed by additional systems installation, and finally the outer surfaces (e.g., finishes) are assembled (this may be presented as different layers in FIG. 6, such as 131 and 132. In this case, wall identification may be determined by scanning a barcode, entering a serial number etc., hence the complete electronic file of the wall may be retrieved.

The AR platform typically analyzes the current wall assembly status by examining the current point cloud, Pr(n). Using object recognition functionality e.g., in an AR software toolbox (e.g. RealityKit software by Apple), existing objects, such as framing elements, water pipes, etc., may be identified. Object type existence or absence (see FIG. 6, objects 133,134), correlated with previous assembly status data (e.g., stages known to be completed or absent, or existence of object types at previous point cloud samples) may be used to indicate likelihood of being at a possible assembly stage (the estimated stage). According to the estimated stage, the plans of the corresponding layers and objects are retrieved, hence creating a virtual point cloud Pv(n) which is registered and anchored relating to Pr(n) and super positioned, resulting in an ultimate point cloud P(n)=Pr(n)+Pv(n) to be used for augmented reality presentation to the end user. Eventually, visuals may be used for quality control by presenting, e.g., displaying to the end user, intended assembled structures which may be compared to the actual assembly progress in the real world. The retrieved virtual point cloud may, for example, be based on the current real physical point cloud e.g., as described above, the retrieved cloud's orientation and location may be matched to the orientation and location of the real cloud and the retrieval and/or reconstruction process may be done in the background, automatically.

In a “multiple stage” process, the system enables an end-user to see beyond a single apartment or a single floor. “Stage” may stand for an observation area such as a floor of a building or other confined areas. For example, if the apartment building has only a single ground floor (e.g., all apartments are on ground zero with some corridor connecting between them) then each apartment (which each include multiple rooms) may be regarded as a different stage. The visualization “depth” determines the number of stages presented; for example, if visualizing only apartments which are neighboring the current apartment, then only a small number of apartments may be retrieved.

In a process performed according to another embodiment (aka “process D”), all or any subset of the following operations d1, d2, . . . . may be performed, suitably ordered e.g., as follows:
d1. Given a multiple stage process: S(1), S(2), . . . , S(K)
d2. Start process and retrieve electronic files of all stages and the completed process
d3. List all objects and layers and their associated inclusion at corresponding stages
d4. Generate current point cloud Pr(n)
d5. Identify current objects in Pr(n)
d6. Create a temporary list of objects and layers and classify as absent or existing (in current point cloud)
d7. If previous point cloud versions exist:
   a. Examine last known process stage
   b. Update list of objects and layers (e.g., as objects may exist but hidden)
d8. Estimate e.g. based on operations (d5) and (d6), current process stage S(i)
d9. Based e.g. on operation (d7) retrieve all existing objects and layers which should exist at stage S(i) e.g. as indicated by operation (d3).
d10. Based e.g. on operation (d9) create a list.
d11. Based e.g. on operations (d9) and (d10), retrieve corresponding electronic files and construct the virtual point cloud Pv(n).
d12. Register and anchor Pv(n) with respect to Pr(n). Super position both to derive the ultimate point cloud Pv(n)
d13. Compare the list generated in operation (d6) (e.g. as updated by operation (d7)) with the list generated in operation (d10). If list is not identical in status, then go to operation (d5).
d14. As all objects and layers physically exist, set process stage as complete
d15. If all stages are complete, then exit. Otherwise go to operation (d4).

Any suitable electronic files representing innards of a building may be employed for any embodiment herein, such as a Revit file representing a layered wall e.g. as described here: https://knowledge.autodesk.com/support/revit/learn-explore/caas/CloudHelp/cloudhelp/2017/ENU/Revit-Model/files/GUID-CCDEE011-2A5E-43AC-BD60-8F81CF432A6B-htm.html

Or such as any digital representation of digital wall cassettes such as but not limited to those described in the following co-owned published patent document:
https://patents.google.com/patent/US20210148115A1/en.

Embodiments herein provide a holistic visualization which systematically exposes the internal and external features of objects, and may, or may not, rely on the user for selecting objects and/or aiding in confirming the objects' positioning within surroundings. This is suitable, inter alia, for industrial use cases of quality control, installation and maintenance, including architectural, construction, manufacturing, and home maintenance use-cases. (e.g., plumbing, electrical) etc.

Example use cases include:

Maintenance—a building is already built and constructed and there is a need to maintain the plumbing system (as an example), and the particulars of this system need to be displayed accurately according to the user's point of view and location.

Assembly—During assembly of the prefabricated wall, internal objects of the wall may be concealed from the end-user and the assembler may need to recover this lost visibility in order to continue the assembly process. For example, consider an internal module (Ma) of the wall which is positioned between wall layers (e.g. crossing through at least one internal layer of the wall) and in addition, another module, Mb, which connects to the previous module Ma (e.g., electrical outlet connecting to a electrical junction box), yet positioned on the layer on top of the previous module Ma. In this scenario, when Mb is installed, Ma is mostly concealed, and it will be advantageous for the assembler to be aware of Ma's location while connecting Mb to Ma. In another example, Ma represents part of the internal framing structure, while Mb represents an isolation layer which connects to the framing structure yet while positioned on top of Ma, the framing structure is concealed.

Quality Control—During manufacturing, visible layers may (e.g., prior to being concealed by additional layers) be compared to a digital reconstructed display of a required layer structure e.g., to allow an assembler or QC inspector to detect missing or misplaced objects (such as cables, MEP elements).

It is appreciated that embodiments herein enhance AR visibility aspects for many applications. From an end-user perspective, it may seamlessly provide visualization of internal structures of objects as part of the complete surrounding environment. Embodiments herein eliminate the need for either expensive hardware which may otherwise be necessary for some applications (e.g., current structure integrity status) yet are considered as an overkill for most other applications (e.g., building maintenance). In addition, embodiments herein eliminate unnecessary physical work effort needed for exposing missing visual information (e.g., by drilling down to an occluded object and/or by removing occluding object portions). Embodiments of the invention facilitate a streamlined implementation with minimal impact on the overall user experience.

It is appreciated that terminology such as “mandatory”, “required”, “need” and “must” refer to implementation choices made within the context of a particular implementation or application described herewithin for clarity and are not intended to be limiting, since, in an alternative implementation, the same elements might be defined as not mandatory and not required, or might even be eliminated altogether.

Components described herein as software may, alternatively, be implemented wholly or partly in hardware and/or firmware, if desired, using conventional techniques, and vice-versa. Each module or component or processor may be centralized in a single physical location or physical device or distributed over several physical locations or physical devices.

Included in the scope of the present disclosure, inter alia, are electromagnetic signals in accordance with the description herein. These may carry computer-readable instructions for performing any or all of the operations of any of the methods shown and described herein, in any suitable order including simultaneous performance of suitable groups of operations, as appropriate. Included in the scope of the present disclosure, inter alia, are machine-readable instructions for performing any or all of the operations of any of the methods shown and described herein, in any suitable order; program storage devices readable by machine, tangibly embodying a program of instructions executable by the machine to perform any or all of the operations of any of the methods shown and described herein, in any suitable order i.e. not necessarily as shown, including performing various operations in parallel or concurrently rather than sequentially as shown; a computer program product comprising a computer useable medium having computer readable program code, such as executable code, having embodied therein, and/or including computer readable program code for performing, any or all of the operations of any of the methods shown and described herein, in any suitable order; any technical effects brought about by any or all of the operations of any of the methods shown and described herein, when performed in any suitable order; any suitable apparatus or device or combination of such, programmed to perform, alone or in combination, any or all of the operations of any of the methods shown and described herein, in any suitable order; electronic devices each including at least one processor and/or cooperating input device and/or output device and operative to perform, e.g. in software, any operations shown and described herein; information storage devices or physical records, such as disks or hard drives, causing at least one computer or other device to be configured so as to carry out any or all of the operations of any of the methods shown and described herein, in any suitable order; at least one program pre-stored, e.g. in memory, or on an information network such as the Internet, before or after being downloaded, which embodies any or all of the operations of any of the methods shown and described herein, in any suitable order, and the method of uploading or downloading such, and a system including server/s and/or client/s for using such; at least one processor configured to perform any combination of the described operations or to execute any combination of the described modules; and hardware which performs any or all of the operations of any of the methods shown and described herein, in any suitable order, either alone or in conjunction with software. Any computer-readable or machine-readable media described herein is intended to include non-transitory computer- or machine-readable media.

Any computations or other forms of analysis described herein may be performed by a suitable computerized method. Any operation or functionality described herein may be wholly or partially computer-implemented e.g., by one or more processors. The invention shown and described herein may include (a) using a computerized method to identify a solution to any of the problems or for any of the objectives described herein, the solution optionally including at least one of a decision, an action, a product, a service or any other information described herein that impacts, in a positive manner, a problem or objectives described herein; and (b) outputting the solution.

The system may, if desired, be implemented as a network—e.g. web-based system employing software, computers, routers and telecommunications equipment, as appropriate.

Any suitable deployment may be employed to provide functionalities e.g., software functionalities shown and described herein. For example, a server may store certain applications, for download to clients, which are executed at the client side, the server side serving only as a storehouse. Any or all functionalities e.g. software functionalities shown and described herein may be deployed in a cloud environment. Clients e.g., mobile communication devices, such as smartphones, may be operatively associated with, but external to the cloud.

The scope of the present invention is not limited to structures and functions specifically described herein and is also intended to include devices which have the capacity to yield a structure, or perform a function, described herein, such that even though users of the device may not use the capacity, they are if they so desire able to modify the device to obtain the structure or function.

Any “if—then” logic described herein is intended to include embodiments in which a processor is programmed to repeatedly determine whether condition x, which is sometimes true and sometimes false, is currently true or false and to perform y each time x is determined to be true, thereby to yield a processor which performs y at least once, typically on an “if and only if” basis e.g. triggered only by determinations that x is true, and never by determinations that x is false.

Any determination of a state or condition described herein, and/or other data generated herein, may be harnessed for any suitable technical effect. For example, the determination may be transmitted or fed to any suitable hardware, firmware or software module, which is known or which is described herein to have capabilities to perform a technical operation responsive to the state or condition. The technical operation may, for example, comprise changing the state or condition, or may more generally cause any outcome which is technically advantageous given the state or condition or data, and/or may prevent at least one outcome which is disadvantageous given the state or condition or data. Alternatively or in addition, an alert may be provided to an appropriate human operator or to an appropriate external system.

Features of the present invention, including operations, which are described in the context of separate embodiments, may also be provided in combination in a single embodiment. For example, a system embodiment is intended to include a corresponding process embodiment and vice versa. Also, each system embodiment is intended to include a server-centered “view” or client centered “view”, or “view” from any other node of the system, of the entire functionality of the system, computer-readable medium, apparatus, including only those functionalities performed at that server or client or node. Features may also be combined with features known in the art and particularly, although not limited to, those described in the Background section or in publications mentioned therein.

Conversely, features of the invention, including operations, which are described for brevity in the context of a single embodiment or in a certain order may be provided separately or in any suitable sub-combination, including with features known in the art (particularly although not limited to those described in the Background section or in publications mentioned therein) or in a different order. “e.g.” is used herein in the sense of a specific example which is not intended to be limiting. Each method may comprise all or any subset of the operations illustrated or described, suitably ordered e.g., as illustrated or described herein.

Devices, apparatus or systems shown coupled in any of the drawings may in fact be integrated into a single platform in certain embodiments or may be coupled via any appropriate wired or wireless coupling, such as but not limited to optical fiber, Ethernet, Wireless LAN, HomePNA, power line communication, cell phone, Smart Phone (e.g. iPhone), Tablet, Laptop, PDA, Blackberry GPRS, Satellite including GPS, or other mobile delivery. It is appreciated that in the description and drawings shown and described herein, functionalities described or illustrated as systems and sub-units thereof can also be provided as methods and operations therewithin, and functionalities described or illustrated as methods and operations therewithin can also be provided as systems and sub-units thereof. The scale used to illustrate various elements in the drawings is merely exemplary and/or appropriate for clarity of presentation and is not intended to be limiting.

Any suitable communication may be employed between separate units herein e.g., wired data communication and/or in short-range radio communication with sensors such as cameras e.g. via WiFi, Bluetooth or Zigbee.

It is appreciated that implementation via a cellular app as described herein is but an example, and, instead, embodiments of the present invention may be implemented, say, as a smartphone SDK; as a hardware component; as an STK application, or as suitable combinations of any of the above.

Any processing functionality illustrated (or described herein) may be executed by any device having a processor, such as but not limited to a mobile telephone, set-top-box, TV, remote desktop computer, game console, tablet, mobile e.g. laptop or other computer terminal, embedded remote unit, which may either be networked itself (may itself be a node in a conventional communication network e.g.) or may be conventionally tethered to a networked device (to a device which is a node in a conventional communication network or is tethered directly or indirectly/ultimately to such a node).

Any operation or characteristic described herein may be performed by another actor outside the scope of the patent application and the description is intended to include apparatus whether hardware, firmware or software which is configured to perform, enable or facilitate that operation or to enable, facilitate or provide that characteristic.

The terms processor or controller or module or logic as used herein are intended to include hardware such as computer microprocessors or hardware processors, which typically have digital memory and processing capacity, such as those available from, say Intel and Advanced Micro Devices (AMD). Any operation or functionality or computation or logic described herein may be implemented entirely or in any part on any suitable circuitry including any such computer microprocessor/s as well as in firmware or in hardware or any combination thereof.

It is appreciated that elements illustrated in more than one drawings, and/or elements in the written description may still be combined into a single embodiment, except if otherwise specifically clarified herewithin. Any of the systems shown and described herein may be used to implement or may be combined with, any of the operations or methods shown and described herein.

It is appreciated that any features, properties, logic, modules, blocks, operations or functionalities described herein, which are, for clarity, described in the context of separate embodiments, may also be provided in combination in a single embodiment, except where the specification or general knowledge specifically indicates that certain teachings are mutually contradictory and cannot be combined. Any of the systems shown and described herein may be used to implement or may be combined with, any of the operations or methods shown and described herein.

Conversely, any modules, blocks, operations or functionalities described herein, which are, for brevity, described in the context of a single embodiment, may also be provided separately or in any suitable sub-combination, including with features known in the art. Each element e.g., operation described herein, may have all characteristics and attributes described or illustrated herein, or, according to other embodiments, may have any subset of the characteristics or attributes described herein.

It is appreciated that apps referred to herein may include a cell app, mobile app, computer app or any other application software. For example, an app may include an input option e.g. virtual button which enables an end-user to elect to see innards of a certain wall and/or an input option to configure which innards are of interest to this specific end-user e.g. an electrician end-user may seek to see only electrical cables inside walls s/he selects whereas a plumber end-user may seek to see only water pipes inside walls s/he selects. A cell app may have various modes of operation depending, say, on whether a building being processed is known to have barcode-identified walls, or known to have RFID tags embedded in its walls, or known to have design files whose name or metadata corresponds to the apartments' number or floor, or none of the above.

Any application may be bundled with a computer and its system software or published separately. The term “phone” and similar used herein is not intended to be limiting and may be replaced or augmented by any device having a processor, such as but not limited to a mobile telephone, or also set-top-box, TV, remote desktop computer, game console, tablet, mobile e.g. laptop or other computer terminal, embedded remote unit, which may either be networked itself (may itself be a node in a conventional communication network e.g.) or may be conventionally tethered to a networked device (to a device which is a node in a conventional communication network or is tethered directly or indirectly/ultimately to such a node). Thus, the computing device may even be disconnected from e.g., WiFi, Bluetooth, etc. but may be tethered directly or ultimately to a networked device.

1. A building monitoring method comprising:
using a hardware processor for determining coordinates of a physical location L within a building and, accordingly,
accessing, from computer memory, at least one design file of the building which pertains to a vicinity of location L and which represents data describing an internal structure of at least one object aka building element within the vicinity of location L.

2. A method according to claim 1 and also comprising superimposing a 3D representation of said internal structure of the at least one building element onto a captured representation of only external features of said vicinity, thereby to yield a superposition of said internal structure and said representation of only external features.

3. A method according to claim 1 and wherein said design files were previously used to construct the building.

4. A method according to claim 2 wherein said superimposing includes aligning the internal structure to the captured representation.

5. A method according to claim 2 and wherein a first subset of the design files of the building which pertains to location L is accessed, and a second subset of the design files of the building which does not pertain to location L is not accessed.

6. A method according to claim 4 wherein said aligning includes analyzing the captured representation for unique external features of the building and finding said unique external features in the design files.

7. A method according to claim 6 wherein the method searches for the unique external features only in a first subset of the design files of the building which pertains to location L and not in a second subset of the design files of the building which does not pertain to location L, thereby to optimize searching for the unique external features.

8. A method according to claim 4 wherein said aligning includes identifying unique tags in the captured representation whose locations within the internal structure are known.

9. A method according to claim 1 wherein said building element comprises a wall having plural interior layers and wherein said internal structure comprises data regarding each of said plural interior layers.

10. A method according to claim 2 and also comprising selecting an access point to a portion of the internal structure of at least one building element which is represented in the 3D representation, by viewing said superposition, and accessing said portion via said access point.

11. A system comprising at least one hardware processor configured to carry out the operations of any of the methods of claims 1-13.

12. A computer program product, comprising a non-transitory tangible computer readable medium having computer readable program code embodied therein, said computer readable program code adapted to be executed to implement a building monitoring method comprising:
from a physical location L within a building,
using a hardware processor for determining coordinates of L and, accordingly,
accessing, from computer memory, at least one design file of the building which pertains to a vicinity of location L and which represents data describing an internal structure of at least one object aka building element within the vicinity of location L.

13. A method according to claim 1 and wherein at least one individual design file from among said design files is treated as though the individual design file were a camera feed including providing a stream of images, synchronized to and oriented to a live feed provided by a physical camera imaging the building, and wherein images in said stream of images are constructed from said at least one design file.

14. A method according to claim 13 and wherein the physical camera is deployed at a location L and wherein the stream of images is constructed from a perspective of a location which equals said location L.

15. A method according to claim 1 wherein the design files also represent external features of said at least one object.

16. A method according to claim 2 wherein a first point cloud is reconstructed from a physical camera which captures the captured representation by scanning at least one room in the building, and a second point cloud is reconstructed from said external features, and wherein said first and second point cloud representations are combined and, accordingly, a representation of the external features and the internal structure is presented to an end-user.

17. A method according to claim 16 and wherein said second point cloud is reconstructed by a hardware processor from a 3D model of at least one object represented by said at least one design file.

18. A method according to claim 1 wherein the design file to access is at least partly determined by detecting a unique identifier of a portion of the building which is of interest and identifying a design file of the building associated in the computer memory with said unique identifier.

19. A method according to claim 18 wherein the unique identifier comprises an RFID tag emedded in the portion of the building.

20. A method according to claim 18 wherein the unique identifier comprises a QR code borne by the portion of the building.

21. A method according to claim 18 wherein the unique identifier comprises a barcode borne by the portion of the building.

22. A method according to claim 21 wherein the portion of the building comprises one of: a wall, a ceiling, a floor, a window, a door.

23. A method according to claim 18 wherein the unique identifier is supplied by control panels which communicate with a scanning application and transmit the unique identification upon request.

24. A method according to claim 23 wherein the unique identifier comprises room verification supplied by a smart home panel.

25. A method according to claim 1 wherein the design file to access is at least partly determined by comparing detected external features of a portion of the building with stored external features of plural portion of the building stored in respective plural design files and selecting a design file from among the plural design files which is most similar to the detected external features.

26. A method according to claim 2 and wherein an orientation in space of the captured representation is determined and wherein the 3d representation of said internal structure is transformed to match said orientation.
